(19) United States
(12) Patent Application Publication
(10) Pub. No.: US 2012/0255603 A1
(43) Pub. Date: Oct. 11, 2012

(54) PHOTOVOLTAIC STRUCTURES AND METHODS OF FABRICATING THEM

(76) Inventors: Young-June Yu, Topsfield, MA (US); Munib Wober, Topsfield, MA (US)

(21) Appl. No.: 13/083,144

(22) Filed: Apr. 8, 2011

(51) Int. Cl. H01L 31/0224; H01L 31/0232

(52) U.S. Cl. 136/256; 438/72; 257/E31.127

(57) ABSTRACT

One device structure includes a substrate on which a surface having alternating concave and convex sections is formed, the surface having alternating concave and convex sections having a number of peaks valleys, a number of electrode/reflector components, each one of the number of electrode/reflector components being conformal to at least a portion of a section of the surface having alternating concave and convex sections from one valley to another valley, a number of p-doped layer, each p-doped layer disposed over at least a portion of an alternate one of the number of electrode/reflector components, a number of n-doped layers, each n-doped layer disposed over at least a portion of other alternate ones of the number of electrode/reflector components. Methods for fabricating are disclosed.

### BACKGROUND

This invention relates generally to photovoltaic structures and methods of fabricating the photovoltaic structures.

A goal of achieving a high efficiency in the solar cells is as important as the goal of producing the low cost solar cells. Advantage of high efficiency solar cells include significantly reduced material cost and production cost and reduced module construction cost and installation costs.

To date, the highest efficiency solar cell in the record has been reported by M. A. Green, who used single crystalline silicon wafers for the device fabrication. The photovoltaic device reported by Green employed a PERL (passivated emitter rear locally diffused) structure as shown in FIG. 1. This PERL structure was able to achieve 25% efficiency by enhancing the light absorption by adopting an inverted pyramid light-trapping scheme, by maximizing the carrier life time using a good passivated surface based on annealed oxide layers on both sides, and by using lightly doped single crystalline materials.

R. A. Sinton et al. presented a back side point contact solar. Sinton et al. reported that 27.5% efficiency has been obtained under 10W/Cm² illumination condition. As shown in FIG. 2, those devices employed a backside point-contact scheme for minimizing the charge loss due to the recombination in the doped region, texturized front surfaces of pyramids for enhanced optical light trapping.

Sanyo Energy Corporation has produced silicon solar cells with efficiency of 23% using the HIT (heterojunction with intrinsic thin layer). SunPower Corporation has produced silicon solar cells with efficiency greater than 21% using the structure similar to FIG. 2.

There is a need to provide silicon solar cells with higher efficiency.

### BRIEF SUMMARY

Embodiments of the device structure of these teachings and methods of these teachings for fabricating the photovoltaic device structure are disclosed herein below.

In one embodiment, a device structure of these teachings includes a substrate on which a surface having alternating concave and convex sections surface is formed, the surface having a plurality of peaks (peaks as used herein may include a plateau) and valleys, each peak disposed between two neighboring valleys (valley as used herein may include a substantially flat section), a number of electrode/reflector components, each one of the number of electrode/reflector components being conformal to at least a portion of a section of the surface having alternating concave and convex sections, each electrode/reflector component being electrically isolated from another electrode/reflector component, a number of p-doped layer, each p-doped layer disposed over at least a portion of an alternate one of the number of electrode/reflector components, a number of n-doped layers, each n-doped layer disposed over at least a portion of other alternate one of the number of electrode/reflector components, one electrode/reflector component having the p-doped disposed over the one electrode/reflector component being adjacent to one of the other electrode/reflector components having the n-doped layer disposed over, and intrinsic silicon material disposed between each of the n-doped silicon layers and each of the p-doped silicon layers.

In one instance, the device structure of these teachings also includes a p-doped, delta doped layer located on the back side surface of the substrate (also referred to as on the substrate and above the surface having alternating concave and convex sections). In another instance, the p-doped, delta doped layer include a number of segments, each segment being disposed over one of the n-doped layers.

In another embodiment, the device structure of these teachings also includes at least one anti-reflection layer disposed on the back side surface of the substrate.

In another embodiment, the substrate in the device structure of these teachings is substantially single crystal silicon. In one instance, the substrate is intrinsic silicon. In another instance, the substrate is a lightly doped n type substrate.

In one embodiment, the method of these teachings for fabricating a device structure includes forming a surface having alternating concave and convex sections on an intrinsic type substrate, forming p doped layers over at least a portion of alternate sections of the surface having alternating concave and convex sections each peak disposed between two neighboring valleys, each p doped layer being formed over at least a portion of one alternate section, the alternate sections extending from one valley to another valley and including one peak, forming n doped layers over at least a portion of other alternate sections of the surface having alternating concave and convex sections, each n doped layers being formed over at least a portion of one of the other alternate section; the other alternate sections extending from one valley to another valley and including one peak, and placing one electrode/reflector component in each section of the surface having alternating concave and convex sections, each section extending from one valley to another valley and including one peak, each electrode/reflector component being conformal to at least a portion of the section of the surface having alternating concave and convex sections, A section of each peak (a plateau in one instance) provides an electrical isolation and a gap in the doped layer between two neighboring valleys, each electrode/reflector component being electrically isolated from another electrode/reflector component. In one instance of the above embodiment, the substrate is a substantially single crystal substrate and the surface having alternating concave and convex sections is formed by wet etching along a predetermined crystal orientation surface.

In another embodiment of the method of these teachings for fabricating a device structure, the method includes
(a) forming a surface having alternating concave and convex sections surface on a lightly doped n type substrate,
(b) depositing an intrinsic amorphous silicon layer over the surface having alternating concave and convex sections,
(c) forming p doped amorphous silicon layers over the intrinsic amorphous silicon layer, the p doped amorphous silicon layers covering at least a portion of alternate sections of the surface having alternating concave and convex sections, doped amorphous silicon layer having a gap over a section of each peak (a plateau in one instance) between two neighboring valleys, each p doped amorphous silicon layer being formed over at least a portion of one alternate section, the alternate sections extending from one valley to another valley and including one peak,
(d) forming n doped amorphous silicon layers over the intrinsic amorphous silicon layer, the n doped amorphous silicon layers covering at least a portion of other alternate sections of the surface having alternating concave and convex sections, each n doped amorphous silicon layers being formed over at least a portion of one of the other alternate section, the other alternate sections extending from one valley to another valley and including one peak, and
(e) placing one electrode/reflector component in each section of the surface having alternating concave and convex sections; each section extending from one valley to another valley and including one peak; each electrode/reflector component being conformal to at least a portion of the section of the surface having alternating concave and convex sections, each electrode/reflector component being electrically isolated from another electrode/reflector component in a section of the peak (a plateau in one instance) between two neighboring valleys.

In one instance of the above other embodiment, the substrate is a substantially single crystal substrate and the forming the periodic surface having alternating concave and convex sections is formed by wet etching along a predetermined crystal orientation surface.

A number of other embodiments of the device structure of the method of fabrication of these teachings are also disclosed hereinbelow.

For a better understanding of the present teachings, together with other and further objects thereof, reference is made to the accompanying drawings and detailed description and its scope will be pointed out in the appended claims.

### BRIEF DESCRIPTION OF THE DRAWINGS

FIG. 1 is a schematic representation of a conventional photovoltaic device;

FIG. 2 is a schematic representation of another conventional photovoltaic device;

FIG. 3 is a schematic representation of one embodiment of the device of these teachings;

FIG. 4 is a schematic representation of another embodiment of the device of these teachings;

FIG. 5 is a flowchart representation of one embodiment of the fabrication method of these teachings;

FIGS. 6a-6mm show schematic representations of one embodiment of the device of these teachings at different steps in the embodiment of the fabrication method of these teachings shown in FIG. 5;

FIG. 7 is a schematic representation of yet another embodiment of the device of these teachings;

FIGS. 8a-8h show schematic representations of one embodiment of the device of these teachings at different sub-steps in one step of one embodiment of the fabrication method of these teachings;

FIGS. 9a-9b show schematic representations of another embodiment of the device of these teachings at different steps in another embodiment of the fabrication method of these teachings;

FIG. 10 is a flowchart representation of yet another embodiment of fabrication method of these teachings;

FIGS. 11a-11oo show schematic representations of yet another embodiment of the device of these teachings at different steps in the embodiment of the fabrication method of these teachings shown in FIG. 10;

FIGS. 12a-12b show schematic representations of another embodiment of the device of these teachings at different steps in another embodiment of the fabrication method of these teachings; and

FIG. 13 is a schematic representation of yet another embodiment of the device of these teachings.

### DETAILED DESCRIPTION

The following detailed description is of the currently contemplated modes of carrying out these teachings. The description is not to be taken in a limiting sense, but is made merely for the purpose of illustrating the general principles of these teachings, since the scope of these teachings is best defined by the appended claims.

For a better understanding of the disclosure the following terms are herein defined:

A “delta doped layer” is a layer that has a dopant distribution with high peak concentrations and narrow distribution width. The narrowest one-dimensional dopant profile is obtained when doping atoms are confined to substantially a few of single atomic layers. The “delta doping profile” is characterized by the location of the dopant sheet and the density of doping atoms in the sheet.

A “lightly doped” substrate is a substrate in which the dopant concentration ranges from 0.2×10⁻⁹ to 0.2×10⁻⁷ (dopant concentration, as used herein, is dopant density/intrinsic density) (for example, a dopant density of 10¹³ cm⁻³ to 10¹⁵ cm⁻³ in crystalline silicon, with an intrinsic density of 5×10²² cm⁻³, would result in a dopant concentration of 0.2×10⁻⁹ to 0.2×10⁻⁷).

A surface having alternating concave and convex sections (a concavo convex surface), as used herein, has a plurality of peaks (peaks as used herein may include a plateau) and valleys, each peak disposed between two neighboring valleys (valley as used herein may include a plateau).

In one embodiment, a device structure of these teachings includes a substrate on which a surface having alternating concave and convex sections (in one example, not a limitation of these teachings, a corrugated surface) is formed, the surface having alternating concave and convex sections having a plurality of peaks and valleys, a number of electrode/reflector components (referred to, in one example as “stripe-shape corrugated electrode/reflectors”), each one of the number of electrode/reflector components being conformal to at least a portion of a section of the surface having alternating concave and convex sections, each electrode/reflector component being electrically isolated from another electrode/reflector component, a section of each peak (a plateau in one instance) having an electrical isolation and a gap in the doped layer between two neighboring valleys, a number of p-doped layer, each p-doped layer disposed over at least a portion of an alternate one of the number of electrode/reflector components, a number of n-doped layers, each n-doped layer disposed over at least a portion of other alternate one of the number of electrode/reflector components, one electrode/reflector component having the p-doped disposed over the one electrode/reflector component being adjacent to one of the other electrode/reflector components having the n-doped layer disposed over, and intrinsic silicon material disposed between each of the n-doped silicon layers and each of the p-doped silicon layers (in one example, forming “stripe shape corrugated p and n layers or p and n junctions”) and intrinsic silicon material disposed between each of the n-doped layers and each of the p-doped layers (in one example, forming p-i-n device components).

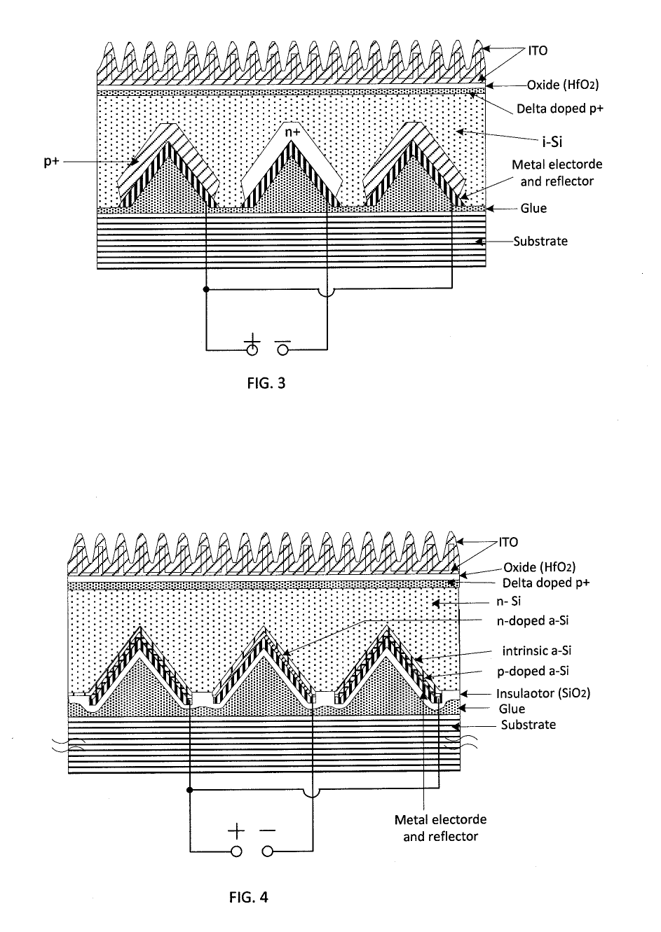

FIG. 3 shows one embodiment of the device structure of these teachings. Referring to FIG. 3, the embodiment shown therein has an intrinsic silicon substrate 10 on which a surface having alternating concave and convex sections (in the embodiment shown, the corrugated V-shaped trench) 20 has been formed. A number of electrode/reflector components 30 (in the embodiment shown, the V-shaped stripe patterned reflection metal layers) are conformal to a portion of the V-shaped trench. A p doped layer 40 (in the embodiment shown, a p doped silicon layer) is disposed over a portion of each of alternate ones of the electrode/reflector components 30. An n doped layer 50 is disposed over a portion of each of other alternate ones all of the electrode/reflector components 30 (in the embodiment shown, an n doped silicon layer-although only one n doped layer is shown in FIG. 3, it should be noted that the pattern shown in the figure repeats and that there are more n doped layers). The electrode/reflector component having the p doped layer disposed over that electrode/reflector component is adjacent to one of the other electrode/reflector component that has the n doped silicon layer disposed over that other electrode reflector component. In that manner a number of p-i-n substructures are formed having a p doped layer and an n doped layer separated by intrinsic silicon.

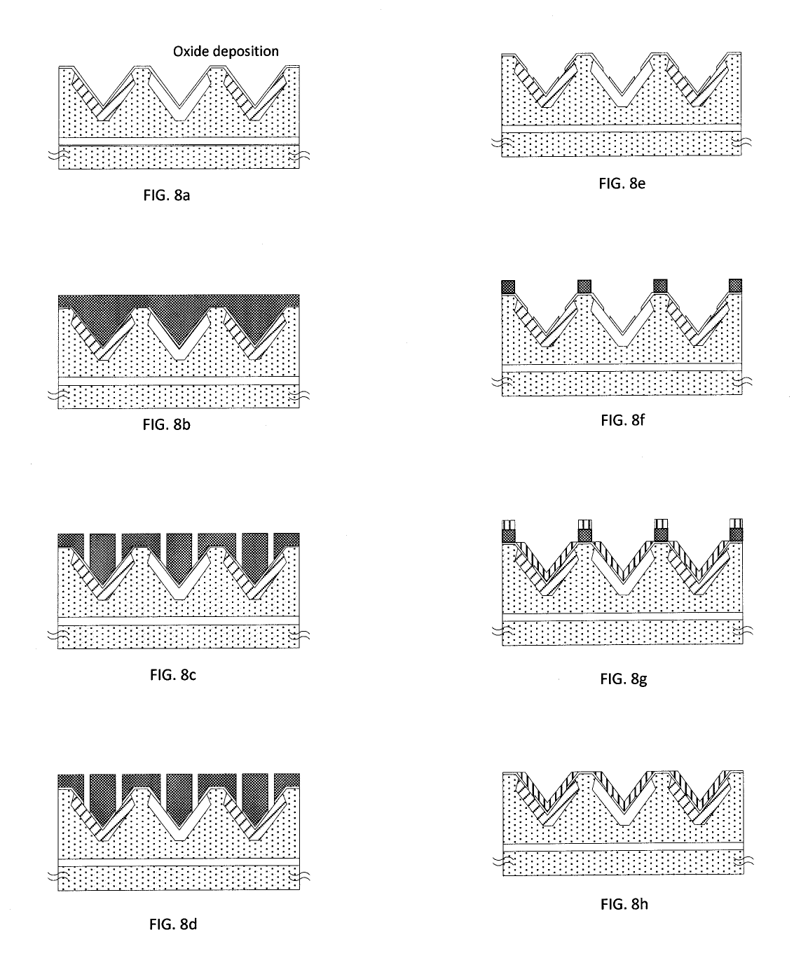

The embodiment shown in FIG. 3 has a p-doped, delta doped layer 60 located in the substrate 10 and above the V-shaped trench 20. In some embodiment, as shown in FIGS. 8a-8b herein below, the p doped, delta doped layer 60 is a segmented layer having a number of segments, each segment being located over one of the n doped layers 50.

The embodiment shown in FIG. 3 has one or more anti-reflection layers 70 disposed on the surface of the substrate 10 and apposite side of the V-shaped trench 20. In the embodiment shown in FIG. 3 the one or more anti-reflection layers 70 includes a number of cone shaped structures 75 (also referred to as nanostructured material). In one exemplary embodiment, not a limitation of these teachings, the refractive index of the nanostructured material should be in the range of 1.7-3.4, and ITO, ZnO, Tantalum oxide, ZIO (zinc indium oxide), ZTO (zinc tin oxide), MgF₂, Si₃N₄, graphene oxide, can be used.

The embodiment shown in FIG. 3 also has a first group of electrical contacts 80 including a first number of electrical contacts and a second group of electrical contacts 85 including a second number of electrical contacts. Each electrical contact from the first group is operatively connected to one of the alternate ones of the electrode/reflector components 30. Each electrical contact from the second group is operatively connected to one of the other alternate ones of the electrode/reflector components. In the embodiment shown in FIG. 3, each electrical contact from the first group 80 is connected in parallel to other electrical contacts from the first group 80 and each electrical contact from the second group 85 is connected in parallel to another electrical contact from the second group 85. It should be noted that although the electrical contacts from each group are shown as connected in parallel, this is not a limitation of these teachings and series connection is also possible.

A substrate 90, in one instance a heat spreading substrate such as, but not limited to, a ceramic material or Al, Cu, ceramic, or CFRP, is attached, by means of glue in the embodiment shown (although this is not a limitation of these teachings) to the electrode/reflector components 30. In one instance, not a limitation of these teachings, the glue 95 is an epoxy glue.

In an exemplary embodiment, these teachings not being limited to only that exemplary embodiment, the thickness of the intrinsic silicon substrate 10 is between about 5μ to 200μ and typically about 20μ, the pitch of the V groove trench is between about 2μ to 50μ and typically about 15μ, the gap (plateau) is between 0.5μ to 5μ and typically 1μ, the depth of the V groove trench is between about 0.5μ to 20μ, and typically about 10μ, the pitch of their nanostructured cones is to the 500 nm to 1μ and typicality 800 nm and the height of the nanostructured cones is between 1μ and 5μ and typicality 2μ.

In one instance, a silicon on insulator (SOI) wafer is used at the starting substrate and subsequently thinned. Wet etching is typically used for thinning the SOI wafer. In one instance the substrate 10 is a substantially single crystal silicon substrate.

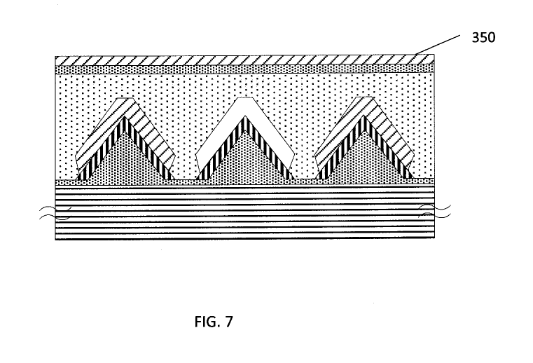

An embodiment of the structure of these teachings, similar to the embodiment shown in FIG. 3 but having a planar type anti-reflection layer 350, is shown in FIG. 7.

Another embodiment of the structure of these teachings is shown in FIG. 4. Referring to FIG. 4, in the embodiment shown therein, the substrate 15 is a lightly n doped silicon substrate. Similar to the embodiment shown in FIG. 3, a surface having alternating concave and convex sections (in the embodiment shown, the corrugated V-shaped trench) 20 is formed on the lightly n doped silicon substrate 15. An intrinsic amorphous silicon layer 25 is disposed over the surface having alternating concave and convex sections 20. A p doped layer amorphous silicon 45 is disposed on the intrinsic amorphous silicon layer 25 and over a portion of each of alternate ones of the electrode/reflector components 30. An n doped amorphous silicon layer 55 is disposed on the amorphous silicon layer 25 and over a portion of each of other alternate ones all of the electrode/reflector components 30 (although only one n doped amorphous silicon layer is shown in FIG. 4, it should be noted that the pattern shown in the figure repeats and that there are more n doped amorphous silicon layers). The electrode/reflector component having the p doped amorphous silicon layer 45 disposed over that electrode/reflector component is adjacent to one of the other electrode/reflector component that has the n doped silicon amorphous silicon layer 55 disposed over that other electrode reflector component. In that manner a number of p-i-n substructures are formed having a p doped amorphous silicon layer and an n doped amorphous silicon layer separated by intrinsic amorphous silicon layer 25. Features in FIG. 4 that are the same as features in FIG. 3 have the same identifying numbers.

A number of the features of the embodiment shown in FIGS. 3 and 4 can result in higher photovoltaic device efficiency. Since the area of the corrugated/reflector (electrode/reflector 30 disposed on the surface having alternating concave and convex sections) is larger than that of a planar-shaped electrode, resistivity of the electrodes is small and almost substantially negligible, resulting in higher photovoltaic efficiency. Secondly, the conformal metal layer functions as a light mirror that reflects the escaping light back to the depletion region between the V-shaped p-i-n junction, resulting in enhanced photovoltaic efficiency. The corrugated p-n junction structure results in a formation of graded electric field inside the silicon bulk in the same direction as the light travels. Photo generated charges can move efficiently toward the electrodes rather than move slowly by diffusion motion, leading to higher photovoltaic efficiency. A delta doped layer is formed on the back surface of the photovoltaic devices. This delta doped layer is beneficial to establish a built-in electric field at the surface to push the charges toward the electrodes, resulting in higher photovoltaic efficiency.

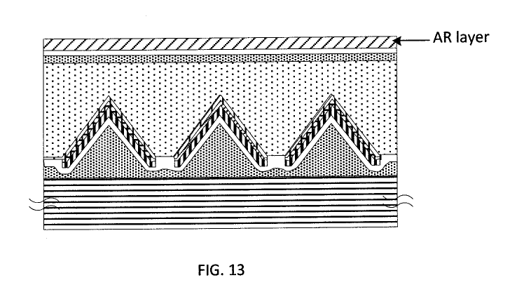

An embodiment of the structure of these teachings, similar to the embodiment shown in FIG. 4 but having a planar type anti-reflection layer 350, is shown in FIG. 13.

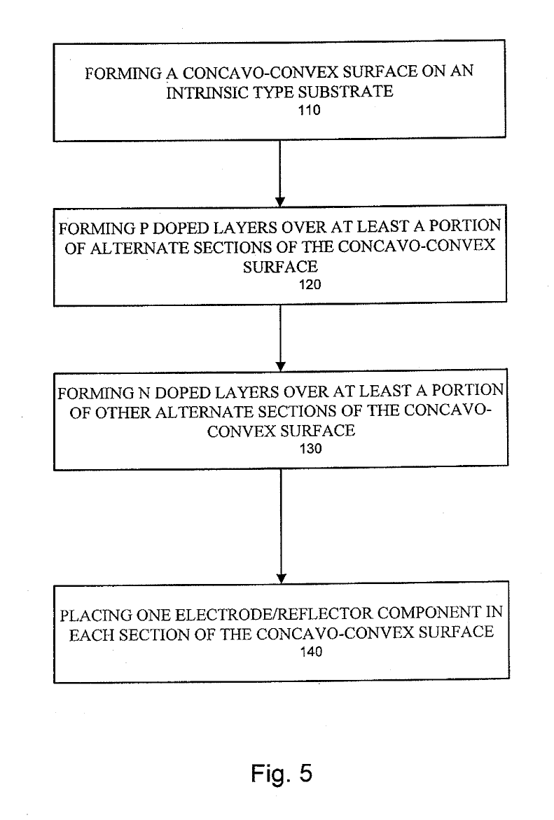

One embodiment of the of the fabrication method of these teachings is shown in FIG. 5. Referring to FIG. 5, the embodiment shown therein includes forming a surface having alternating concave and convex sections on an intrinsic type substrate (step 110, FIG. 5; forming the V-shaped corrugated trench), forming p doped layers over at least a portion of alternate sections of the surface having alternating concave and convex sections (step 120, FIG. 5), each p doped layer being formed over at least a portion of one alternate section, the alternate sections extending from one valley to another valley and including one peak, forming n doped layers over at least a portion of other alternate sections of the surface having alternating concave and convex sections (step 130, FIG. 5), each n doped layers being formed over at least a portion of one of the other alternate section, the other alternate sections extending from one valley to another valley and including one peak (p and n doped layers in the trenches), and placing one electrode/reflector component in each section of the surface having alternating concave and convex sections (step 140, FIG. 5), each section extending from one valley to another valley and including one peak, each electrode/reflector component being conformal to at least a portion of the section of the surface having alternating concave and convex sections; each electrode/reflector component being electrically isolated from another electrode/reflector component over a section of the peak (a plateau in one instance) between the two neighboring valleys. In one instance of the above embodiment, the substrate is a substantially single crystal substrate and the surface having alternating concave and convex sections is formed by wet etching along a predetermined crystal orientation surface (in one instance, not a limitation of these teachings, the 111 crystal orientation surface). In one instance, the starting substrate is a silicon on insulator (SOI) wafer. An SOI wafer is easy to thin by a wet etch process, because wet etch stops at the buried oxide (BOX) layer interface.

In another instance, the method includes forming a p-doped, delta doped layer located on back side surface of the substrate. In one instance, the delta doped layer is formed by a low temperature process such as atomic layer deposition (ALD), molecular beam epitaxy (MBE), chemical vapor deposition (CVD) or conventional ion implantation technique, followed by rapid thermal annealing or laser annealing. In another instance of the forming of the delta layer, the method includes forming a plurality of segments of the p-doped, delta doped layer, each segment from the number of segments being disposed over the n-doped layers.

In another instance of the embodiment shown in FIG. 5, the method includes forming electrical contacts on the p doped layers and the n doped layers. In another embodiment, the method shown in FIG. 5 also includes placing one or more anti-reflection layers on the back side of the substrate. In one instance, the placing of the one or more anti-reflection layers comprises forming one or more anti-reflection layer having a number of cone shaped structures. In another instance, the placing of the one or more anti-reflection layers comprises forming one or more planar anti-reflection layer.

In yet another instance of the embodiment shown in FIG. 5, the method includes depositing a passivation layer on substrate before placing the one or more anti-reflection layers, the one or more anti-reflection layers being placed on the passivation layer. The passivation layer can, but is not limited to, be deposited by ALD.

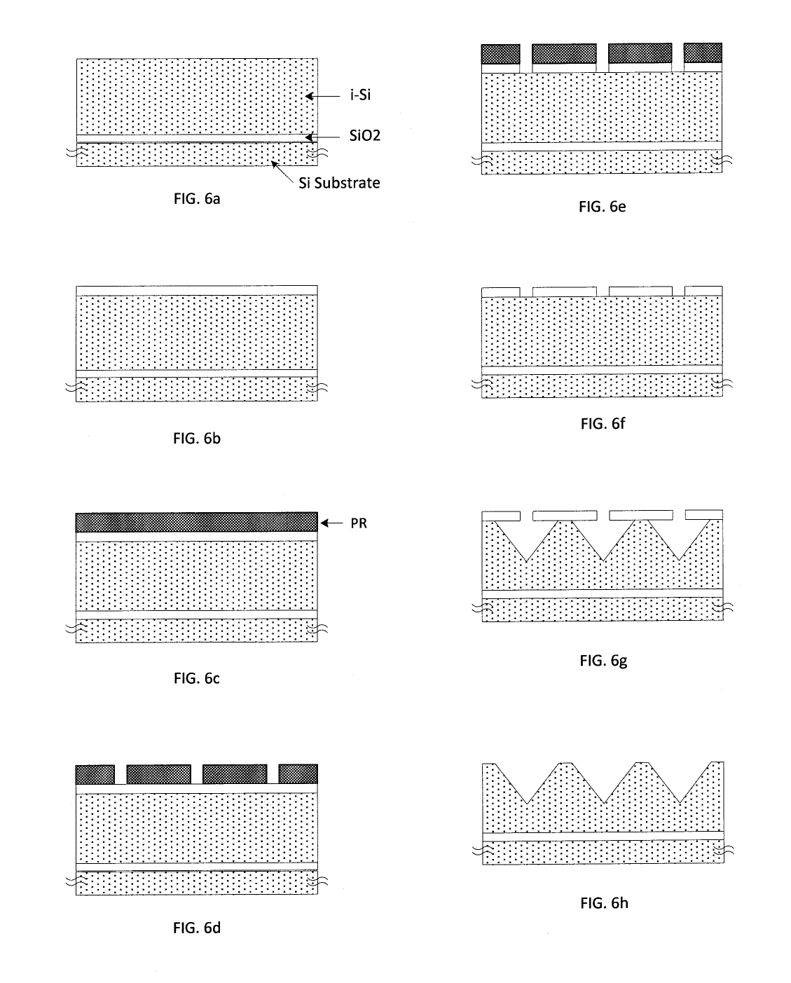

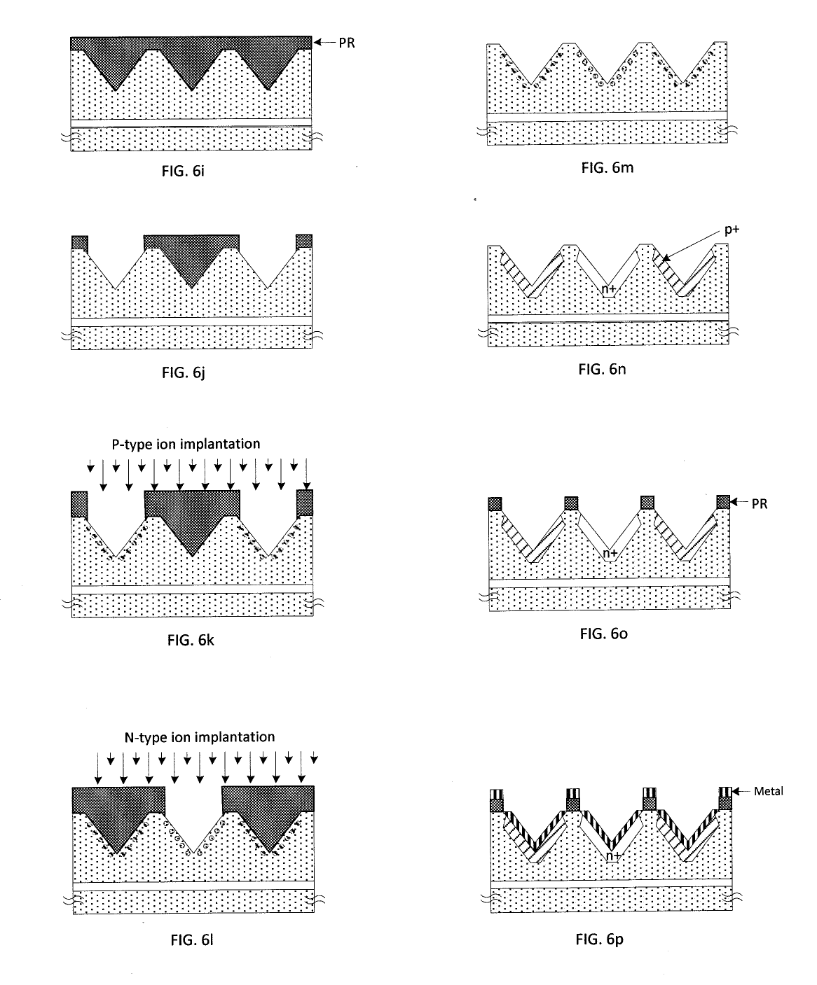

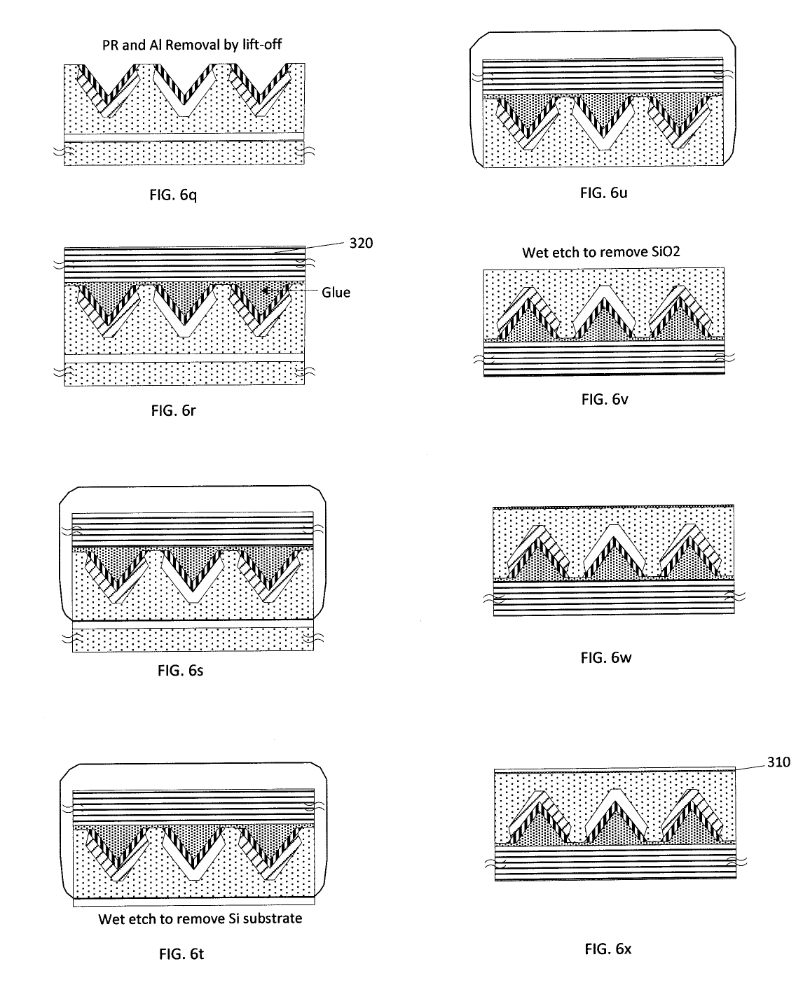

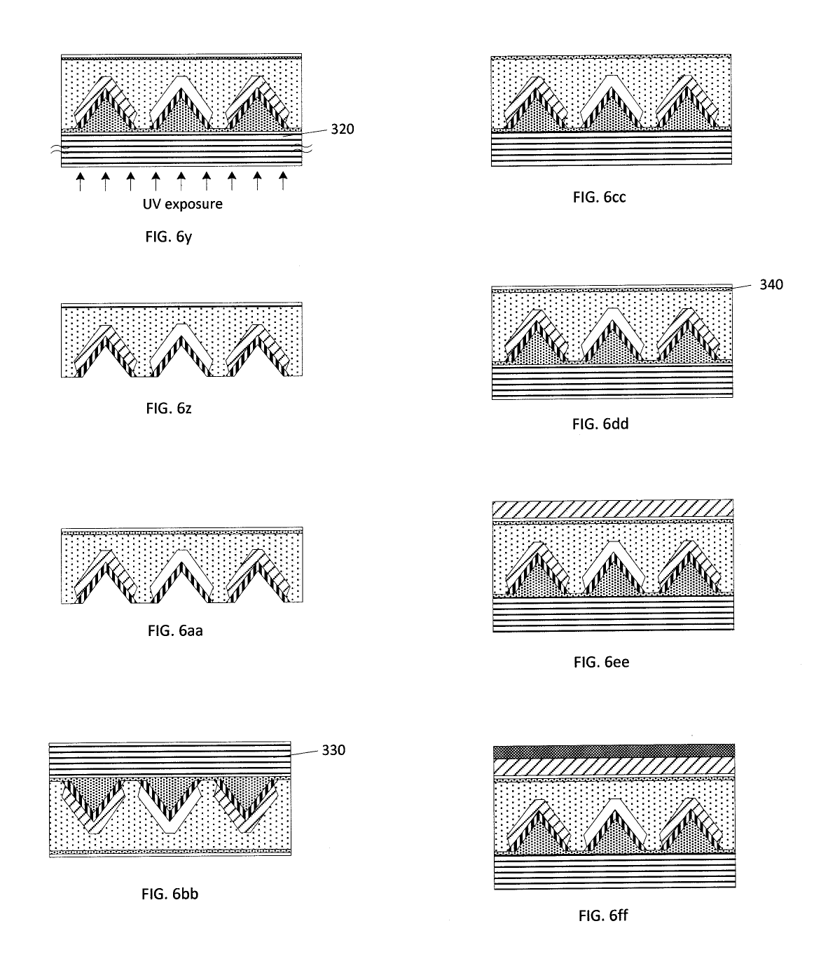

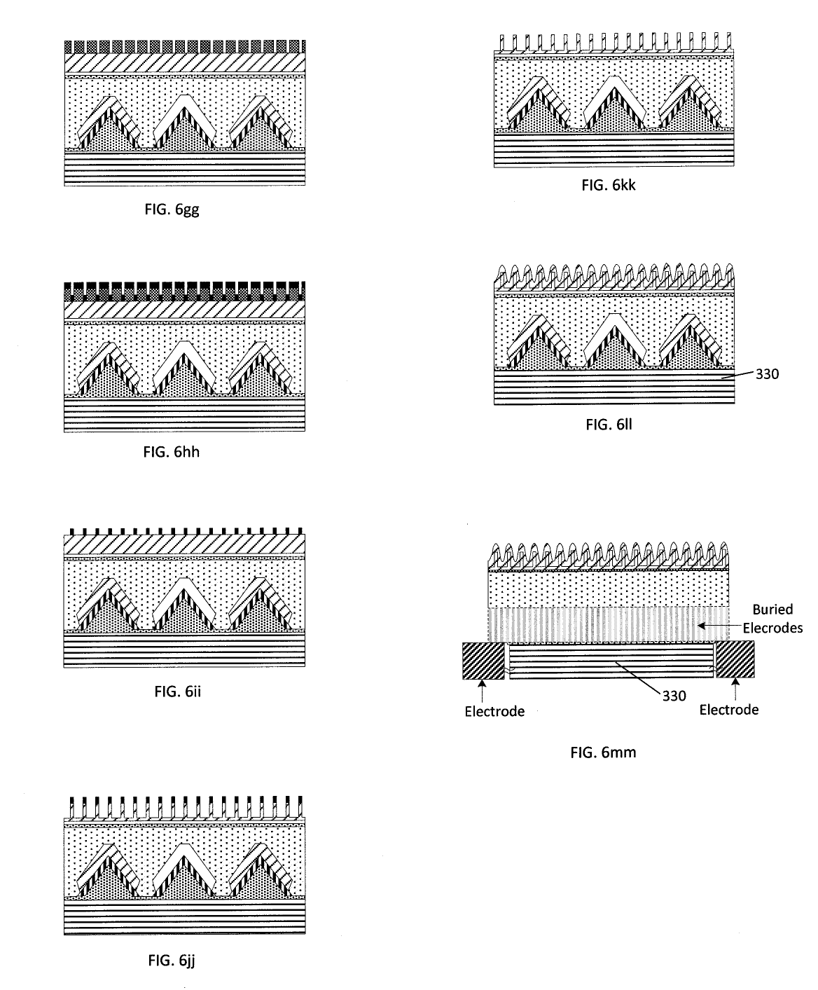

FIGS. 6a-6mm show schematic representations of one embodiment of the device of these teachings at different steps in the embodiment of the fabrication method of these teachings shown in FIG. 5. Referring to FIG. 6a, the structure shown therein 1000 is the starting material. In one instance, the starting material is a SOI (silicon on insulator) wafer with an undoped intrinsic silicon. Other semiconductor materials such as group III-V or Group II-VI compound semiconductors can be used.

Referring to FIG. 6b, in the structure shown therein 1001, oxide layer is deposited on the top. In one exemplary embodiment, not a limitation of the teachings, thickness of the oxide is about 20 nm to 200 nm.

Referring to FIG. 6c, in the structure shown therein 1002, photo resist (PR) is deposited for the preparation of the lithography. Referring to FIG. 6d, in the structure shown therein 1003, the photo resist is patterned to have stripes by employing a conventional photo lithography technique. In one exemplary embodiment, not a limitation of his teachings, the width of the stripe is about 2 μm, and the gap is about 13 μm, if a 15 um pitch is desired.

Referring to FIG. 6e, in the structure shown therein 1004, the oxide cap layer is exposed by the photo resist pattern is removed by employing the dry etch (or reactive ion etching (RIE etch)). Referring to FIG. 6f, in the structure shown therein 1005, the photo resist mask is removed by a photo resist etchant and a cleaning process is performed.

Referring to FIG. 6g, in the structure 1006 shown therein, wet etch is applied using the stripe-shaped oxide pattern as a etch mask. Then, the substrate is etched anisotropically by forming V-shaped trenches. In one instance, the surfaces of the V-shaped trenches are aligned parallel to the (111) crystalline axis of the Si. As a silicon etchant, KOH is used. After the etching process is finished, the silicon wafer is cleaned with DI water.

Referring to FIG. 6h, in the structure 1007 shown therein, the oxide mask layer is removed by wet etch using the Hydrofluoric acid (HF) solution. Referring to FIG. 6i, in the structure 1008 shown therein, photo resist is placed on the top of the wafer using the spin coating. Referring to FIG. 6i, in the structure 1009 shown therein, a lithography is applied to form the photo resist pattern such that odd numbered V-shaped stripe trenches can be exposed.

Referring to FIG. 6k, in the structure 1010 shown therein, ion implantation is applied to the exposed trenches. In an exemplary embodiment, not a limitation of these teachings, boron is typically used as a p-type dopant. In one instance, to form the graded p layer having the p+ near the surface and p− in the bulk, series of at least two ion implantations are performed, for example, low energy implantation with high dose is followed by high energy implantation with low dose, or vice versa. The photo resist mask is removed afterwards.

Referring to FIG. 6l, in the structure 1011 shown therein, the steps performed to arrive structures 1008 through 1010 are repeated for the even numbered trenches to expose and ion implant with n-type dopant in this case. Referring to FIG. 6m, in the structure 1012 shown therein, the photo resist mask is removed and the wafer is cleaned.

Referring to FIG. 6n, in the structure 1013 shown therein 1013, thermal annealing is applied. In one exemplary embodiment, not a limitation of these teachings, the thermal annealing is performed under the Argon environment at about 850 C for about 10 to about 30 min.

Referring to FIG. 6o, in the structure 1014 shown therein, the photo resist is placed only on the top of the plateaus using, for example, a lithography method or stamping method.

Referring to FIG. 6p, in the structure 1015 shown therein, a metal is deposited anisotropically to cover the exposed area as well as the top of the photo resist. Typical metal, these teachings not being limited to only those typical or exemplary metals, for this electrode formation is aluminum (AL). Other exemplary metals such as Au, Ag, Cr, Cu, Ni, Ti, a combination of thereof can also be used.

Referring to FIG. 6q, in the structure 1016 shown therein, lift-off etch is employed for removing the photo resist and the unwanted metal on it. After the lift-off, the metal is annealed for making a good ohmic contact with the doped silicon.

Referring to FIG. 6r, in the structure 1017 shown therein, a substantially transparent substrate 320, such as, but not limited to, a glass plate, is bonded, using glue, to the surface on which the metal was deposited on in FIG. 6p. In one embodiment, a glue allowing removal by UV exposure is utilized; in that embodiment, the glass substrate 320 can be removed later.

Referring to FIG. 6s, in the structure 1018 shown therein, a wax is deposited on the substrate and sidewall of the wafer to block the wet etch in the next step. Referring to FIG. 6t, in the structure 1019 shown therein, A wet etch process is employed to thin the wafer by using KOH as an etchant. This etch process removes the handling silicon layer and stops at the SiO₂ interface. Referring to FIG. 6u, in the structure 1020 shown therein, another wet etch process is employed to remove the SiO₂ by using diluted HF as an etchant. Referring to FIG. 6v, in the structure 1021 shown therein, the wax deposited on the substrate and sidewall of the wafer is removed.

Referring to FIG. 6w, in the structure 1022 shown therein, a thin p-type dopant layer (also referred to as the p doped, delta doped layer) is formed by deposition. In one instance, the p doped, delta doped layer is formed by either by ALD, or CVD. An ALD (atomic layer deposition) technique is typically employed because it deposits without using any plasma energy which tends to damage the silicon surface. The dopant layer can comprise any suitable material, such as, but not limited to, trimethylboron, triisopropylborane ((C₃H₇)₃B), triethoxyborane ((C₂H_{S}O)₃B, and/or triisopropoxyborane ((C₃H₇O)₃B.

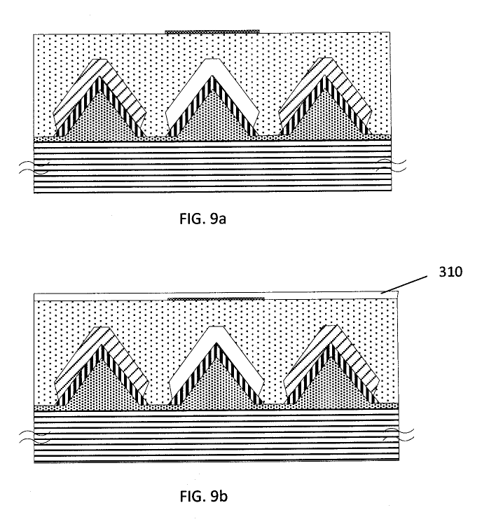

Alternatively, p-type dopant can be implanted by using a conventional ion implantation technique. In this case, the steps producing the structures 1020 and 1023 can be operated. The p-dopant layer, in one instance, can be formed only above substantially the n junction, as shown in FIGS. 9a, 9b (structures 1022B and 1023B). The conventional ion implantation forms a modulated delta doping layer. In the instance that the delta doping layer is a p-type, it is beneficial for electron collection. Unlike photo detectors which collect only a single type of carrier, a photovoltaic device can collect holes and electrons. Having a p doped, delta doping layer over the entire group of p-i-n junctions may not be beneficial for collecting other type of carrier. A modulated p doped, delta doping layer disposed only above substantially the n junctions can enhance the collection of electrons.

Referring to FIG. 6x, in the structure 1023 shown therein, a thin oxide (in one instance, SiO₂) 310 is deposited so that the dopant layer (the delta doped layer) is sandwiched between the silicon and the oxide layer. In one instance, the scene oxide is deposited by ALD.

Referring to FIG. 6y, in the structure 1024 shown therein, the substantially transparent substrate 320 is detached from the wafer. In one instance, the detachment of the substantially transparent substrate 320 is a result of UV exposure.

Referring to FIG. 6z, in the structure 1025 shown therein, the detached wafer is cleaned in order to remove substantially any remaining glue.

Referring to FIG. 6aa, in the structure 1026 shown therein, the dopant is diffused into silicon for forming a shallow, thin p+ doped layer, so called, ‘delta doped layer’ which will result in the surface pinning. In one instance, rapid thermal annealing is employed to implement the diffusion. In one exemplary embodiment, not a limitation of these teachings, the thermal annealing is performed at about 850° C. for about 10 to about 30 minutes under a suitable atmosphere (for example, but not limited to, argon).

Referring to FIG. 6bb, in the structure 1027 shown therein, another substrate 330 is attached for providing a mechanical support as well as for heat spreading. In one instance, a heat conductive glue is deposited on the surface having the grooved electrodes. Then, the substrate 370 is attached. In one typical embodiment, not a limitation of these teachings, a ceramic plate can be used. Other materials such as AL, Cu, Stainless still, carbon fiber reinforced polymer (CFRP), with combination of thereof can be utilized for the substrate 330. It should be noted that these teachings are not limited to only those materials.

Referring to FIG. 6cc, in the structure 1028 shown therein, the thin oxide layer at the surface of the wafer is removed by wet etch using buffered HF. The wafer surface is cleaned afterwards.

Referring to FIG. 6dd, in the structure 1029 shown therein, a thin passivation layer 340 is supposed. In one instance, a Thin HfO₂ layer is deposited as the passivation layer. Other materials such as SiO₂, Al₂O₃, can be used as a passivation layer.

Referring to FIG. 6ee, in the structure 1030 shown therein, an ITO (Indium Tin oxide) layer is deposited by using sputtering or CVD processes. In one instance, the thickness of the deposited ITO is about 1.7 micron. Other materials such as ZnO, ZIO, ZTO, MgF₂, graphene oxide, TiO2, and nitride can be used. For embodiments having a planar antireflection layer, as in the structure 1030B shown in FIG. 7, the thickness of the ITO is determined by the desired antireflection property. In one instance, these teachings not being limited to only that instance, for embodiments having a planar antireflection layer, the thickness of the ITO can be about a quarter wavelength of green light, which is the middle of the visible spectrum. For embodiments having a planar reflection layer, the steps necessary to obtain the structures 1031-1037 in FIGS. 6ff through 6ll can be omitted.

Referring to FIG. 6ff, in the structure 1031 shown therein, photo resist is deposited on the ITO. In one instance, the photo resist is deposited by means of a spin coating method. Referring to FIG. 6gg, in the structure 1032 shown therein, the photo resist is patterned. In one instance, the photo resist is patterned by means of e-beam lithography. In one embodiment, not a limitation of these teachings, the shape of the pattern is typically an array of circular holes with about 100 nm diameter and about 800 nm pitch.

Referring to FIG. 6hh, in the structure 1033 shown therein, Aluminum is deposited on the patterned photo resist and the exposed ITO. In one instance, the Aluminum is deposited by using evaporation or sputtering processes.

Referring to FIG. 6ii, in the structure 1034 shown therein, photo resist is removed as well as the Al on the PR mask by lift-off process.

Referring to FIG. 6jj, in the structure 1035 shown therein, an ITO pillar array is constructed. In one instance, a dry etch process is employed to make the ITO pillar array. In one exemplary embodiment, not a limitation of these teachings, the ITO pillar array has a height about a 1.5 micron, about a diameter of about 100 nm, and a pitch of about 800 nm.

Referring to FIG. 6kk, in the structure 1036 shown therein, AI is removed from the ITO pillars. In one instance, the Al is removed by means of wet etching.

Referring to FIG. 6ll, in the structure 1037 shown therein, ITO is deposited conformally so that end result may form an array of the inverted parabolic cones. In one instance, the ITO is deposited by a combination of ALD and CVD.

Referring to FIG. 6mm, in the structure 1038 shown therein, the edge of the substrate 330 is removed and electrical contacts are formed to connect the V-groove shaped electrodes.

FIGS. 8a-8h show schematic representations of one embodiment of the device of these teachings at different sub-steps in fabricating electrical contacts in the fabrication method shown in FIG. 5. Referring to FIG. 8a, in the structure 2000 shown therein, insulating oxide is the positive on the surface with the V-trenches (the surface having alternating concave and convex sections). In one instance, the insulating oxide is formed thermally. In another instance, ALD and CVD processes can be used to deposit the oxide (in one embodiment, not a limitation of these teachings, SiO₂). In one exemplary embodiment, not a limitation of these teachings, the oxide has a thickness of about 10 nm to about 50 nm.

Referring to FIG. 8b, in the structure 2001 shown therein, photo resist is deposited over the oxide. In one instance, the photo resist is deposited utilizing spin coating.

Referring to FIG. 8c, in the structure 2002 shown therein, circular-shaped pattern is formed at each slope of the V-shaped trenches, using a conventional lithography technique. Referring to FIG. 8d, in the structure 2003 shown therein, a portion of the oxide layer is removed. In one instance, Dry etch is utilized to remove the portion of the oxide layer which is exposed through the photo resist mask.

Referring to FIG. 8e, in the structure 2004 shown therein, the photo resist mask is removed. In one instance, the photo resist mask is removed by wet etching.

Referring to FIG. 8f, in the structure 2005 shown therein, photo resist is placed only on the top of the plateaus of the surface having alternating concave and convex sections. In one instance, the placing of the photo resist these perform utilizing a conventional lithography method or a printing method.

Referring to FIG. 8g, in the structure 2006 shown therein, a metal is deposited over the V-trenches and the photo resist. In one instance the metal is deposited anisotropically to cover the exposed area as well as over the photo resist. Typical metal, these teachings not being limited only to this metal, for the electrode formation is aluminum (AL). Other metals, such as, but not limited to, Au, Ag, Cr, Cu, Ni, Ti, a combination of thereof can be used.

Referring to FIG. 8h, in the structure 2007 shown therein, the photo resist and the metal on the photo resist are removed. In one instance, Lift-off etch is utilized in removing the photo resist and the unwanted metal on the photo resist. After removing the photo resist and the metal of the photo resist, the remaining metal is annealed in order to ensure adequate ohmic contact with the doped silicon.

FIGS. 9a-9b show schematic representations of another embodiment of the device of these teachings at different steps in the forming the p-doped, delta doped layer (in the embodiment in which the p-doped, delta doped layer has a number of segments) steps in the embodiment of the fabrication method of these teachings shown in FIG. 5. Referring to FIGS. 9a-9, a p-dopant layer formed only substantially above the n junction is shown therein.

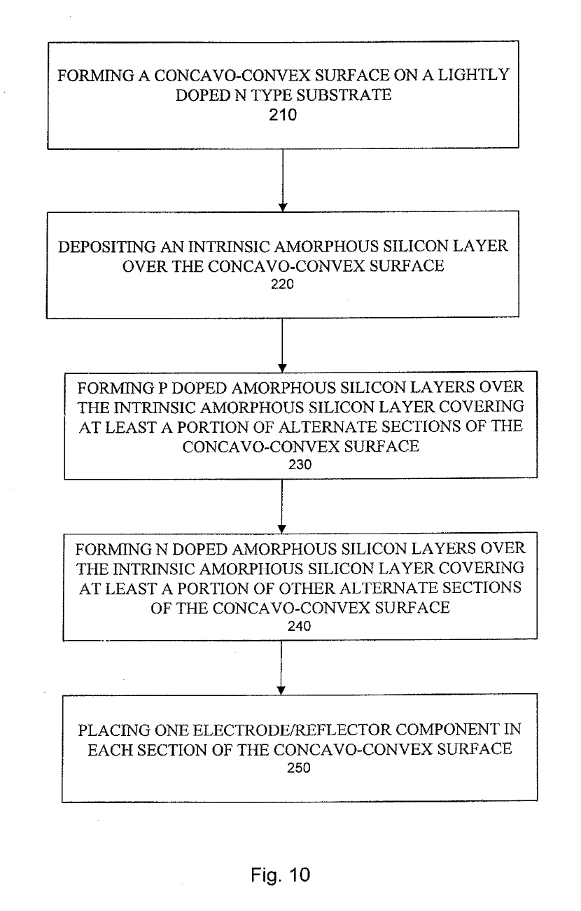

Another embodiment of the of the fabrication method of these teachings is shown in FIG. 10. Referring to FIG. 10, the embodiment shown therein includes
(a) forming a surface having alternating concave and convex sections on a lightly doped (step 210, FIG. 10; forming the V-shaped corrugated trench) (10 cm⁻³ to 10¹⁵ cm⁻³n type substrate,
(b) depositing an intrinsic amorphous silicon layer over the surface having alternating concave and convex sections (step 220, FIG. 10),
(c) forming p doped amorphous silicon layers over the intrinsic amorphous silicon layer (step 230, FIG. 10), the p doped amorphous silicon layers covering at least a portion of alternate sections of the surface having alternating concave and convex sections, each p doped amorphous silicon layer being formed over at least a portion of one alternate section, the alternate sections extending from one valley to another valley and including one peak,
(d) forming n doped amorphous silicon layers over the intrinsic amorphous silicon layer (step 240, FIG. 10, the n doped amorphous silicon layers covering at least a portion of other alternate sections of the surface having alternating concave and convex sections, each n doped amorphous silicon layers being formed over at least a portion of one of the other alternate section, the other alternate sections extending from one valley to another valley and including one peak, and
(e) placing one electrode/reflector component in each section of the surface having alternating concave and convex sections (step 250, FIG. 10), each section extending from one valley to another valley and including one peak, each electrode/reflector component being conformal to at least a portion of the section of the concavo convex surface, each electrode/reflector component being electrically isolated from another electrode/reflector component over the plateau between two neighboring valleys.

In one instance of the embodiment shown in FIG. 10, the substrate is a substantially single crystal substrate and the surface having alternating concave and convex sections is formed by wet etching along a predetermined crystal orientation surface (in one instance, not a limitation of these teachings, the 111 crystal orientation surface). In one instance, the starting substrate is a silicon on insulator (SOI) wafer. An SOI wafer is easy to thin by a wet etch process, because wet etch stops at the buried oxide (BOX) layer interface.

In another instance of the embodiment shown in FIG. 10, the method includes forming a p-doped, delta doped layer located on back side of the substrate. In one instance, the delta doped layer is formed by a low temperature process such as atomic layer deposition (ALD), molecular beam epitaxy (MBE), chemical vapor deposition (CVD) or conventional ion implantation technique, followed by rapid thermal annealing or laser annealing. In another instance of the forming of the delta layer, the method includes forming a plurality of segments of the p-doped, delta doped layer, each segment from the number of segments being disposed on the opposing side of the n-doped layers.

In another instance of the embodiment shown in FIG. 10, the method includes forming electrical contacts on the p doped layers and the n doped layers. In another embodiment, the method shown in FIG. 10 also includes placing one or more anti-reflection layers on back side of the substrate. In one instance, the placing of the one or more anti-reflection layers comprises forming one or more anti-reflection layer having a number of cone shaped structures. In another instance, as shown in FIG. 13, the placing of the one or more anti-reflection layers comprises forming one or more planar anti-reflection layer.

In yet another instance of the embodiment shown in FIG. 10, the method includes depositing a passivation layer on substrate before placing the one or more anti-reflection layers, the one or more anti-reflection layers being placed on the passivation layer. The passivation layer can, but is not limited to, be deposited by ALD.

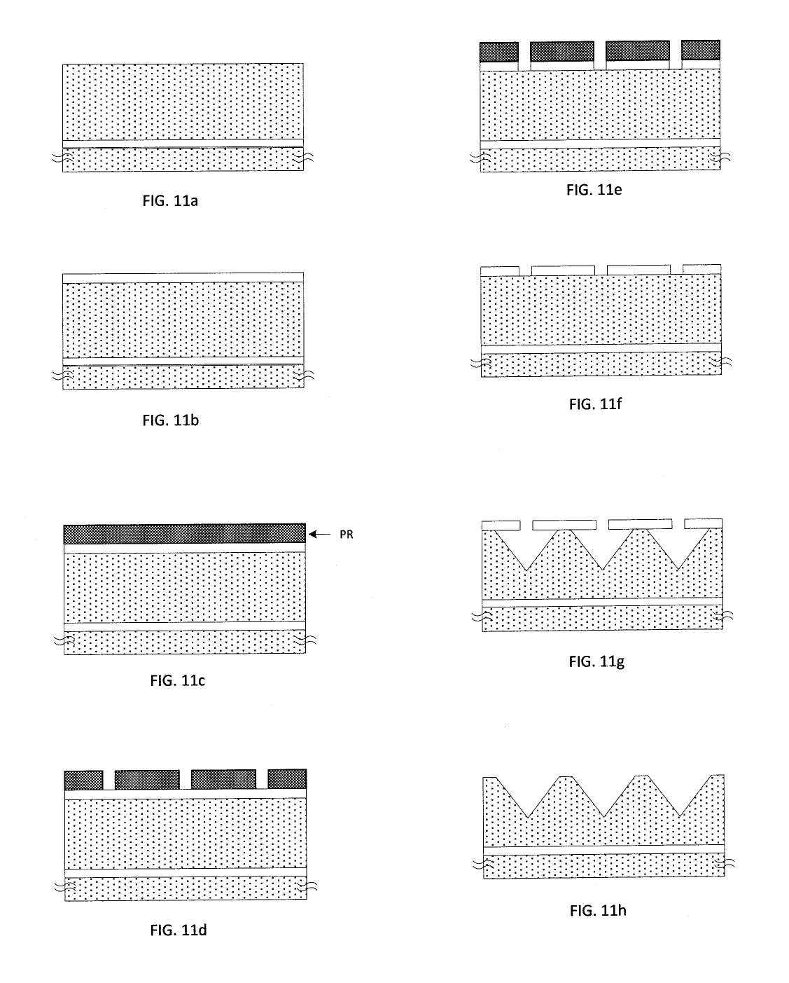

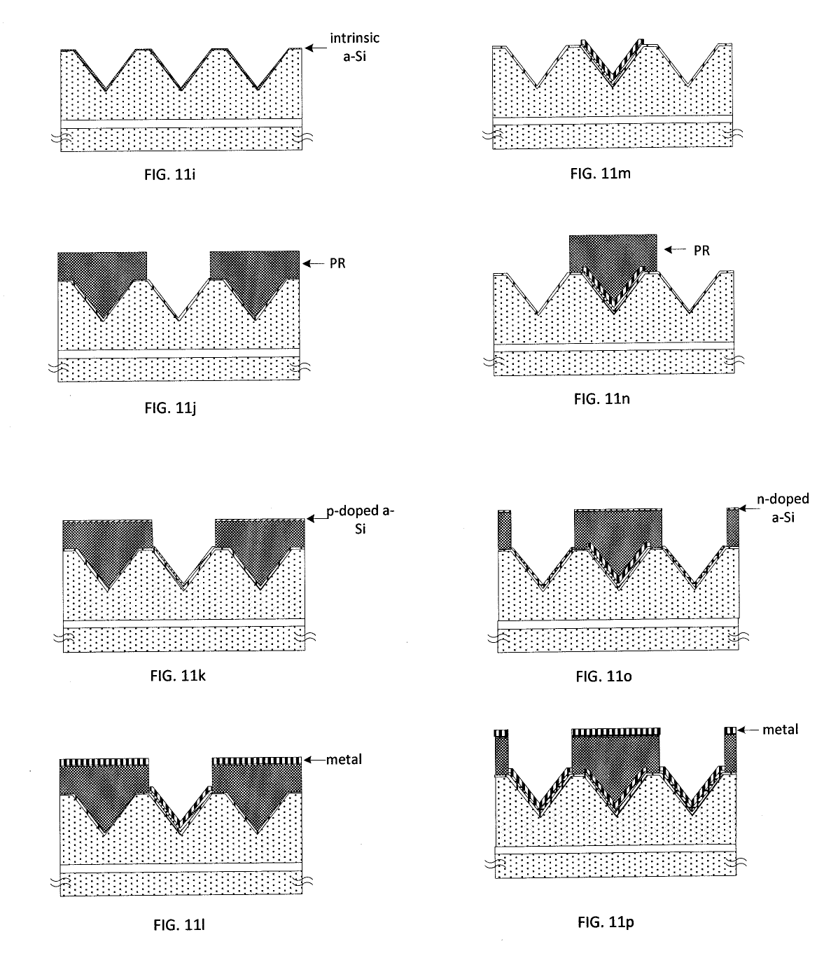

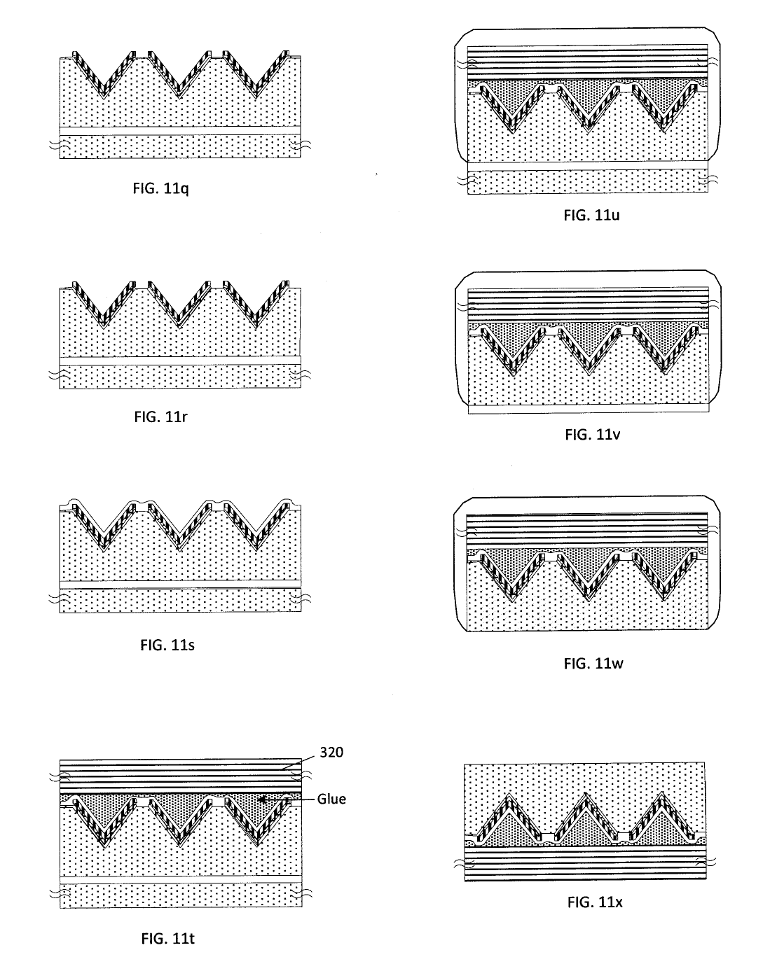

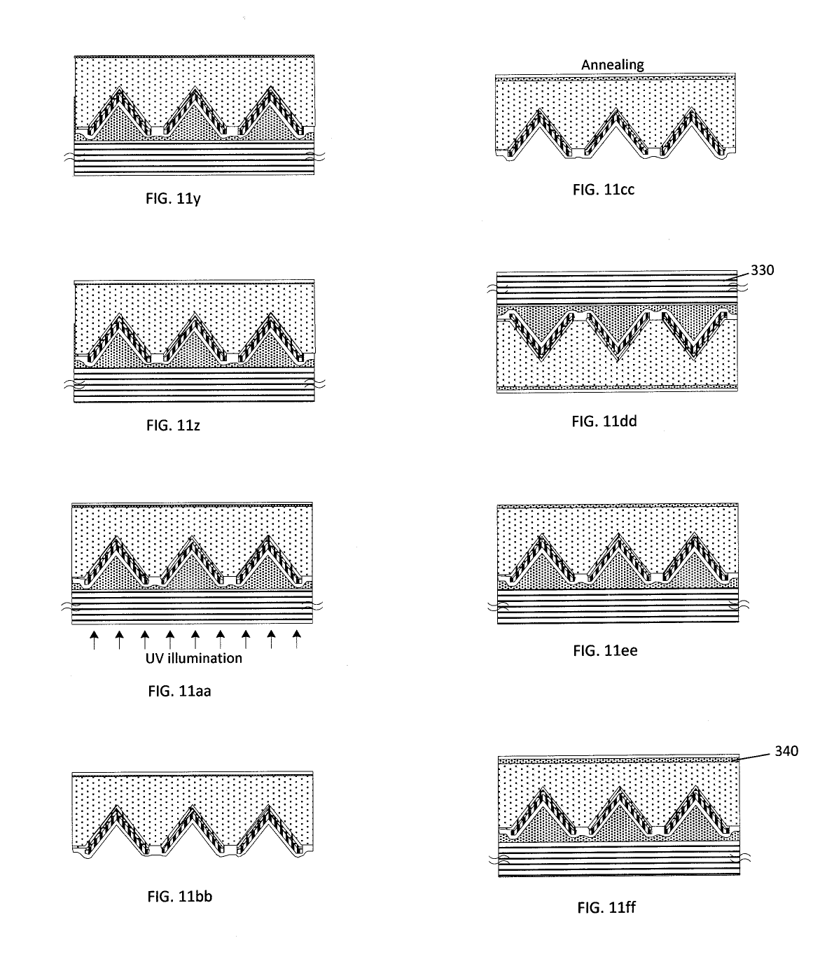

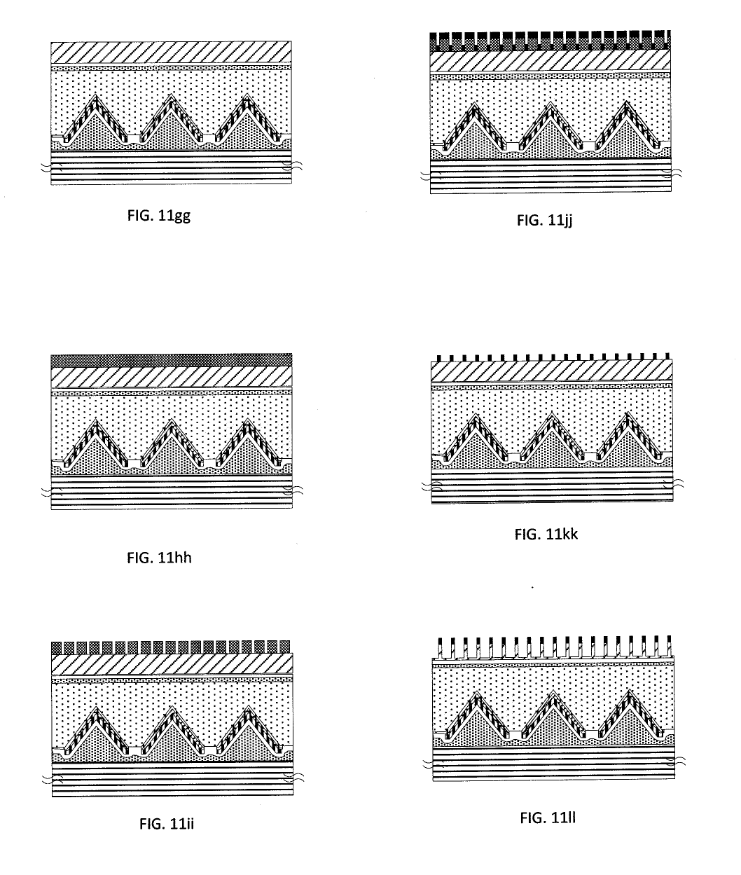

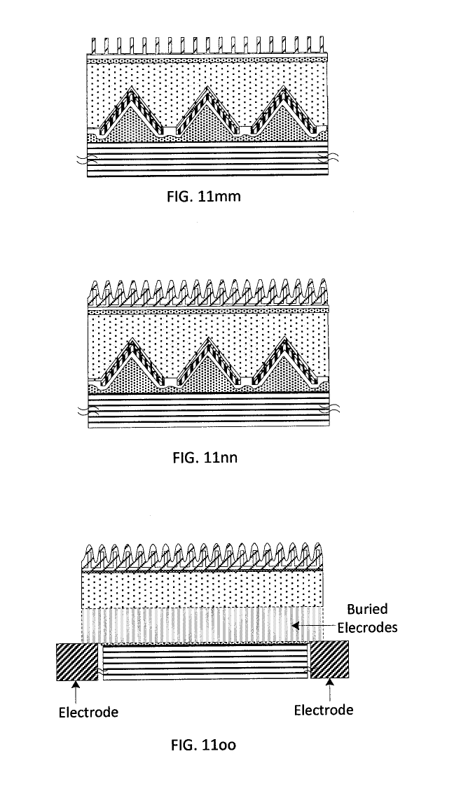

FIGS. 11a-11oo show schematic representations of one embodiment of the device of these teachings at different steps in the embodiment of the fabrication method of these teachings shown in FIG. 10. Referring to FIG. 11a, the structure shown therein 3000 is the starting material. In one instance, the starting material is a SOI (silicon on insulator) wafer with an a lightly doped n-type silicon above the buried oxide layer. Other semiconductor materials such as group III-V or Group II-VI compound semiconductors can be used.

Referring to FIG. 11b, in the structure shown therein 3001, oxide layer is deposited on the top. In one exemplary embodiment, not a limitation of the teachings, thickness of the oxide is about 20 nm to 200 nm.

Referring to FIG. 11c, in the structure shown therein 3002, photo resist (PR) is deposited for the preparation of the lithography. Referring to FIG. 11d, in the structure shown therein 3003, the photo resist is patterned to have stripes by employing a conventional photo lithography technique. In one exemplary embodiment, not a limitation of his teachings, the width of the stripe is about 2 um, and the gap is about 13 um, if a 15 um pitch is desired.

Referring to FIG. 11e, in the structure shown therein 3004, the oxide cap layer is exposed by the photo resist pattern is removed by employing the dry etch (or reactive ion etching (RIE etch)). Referring to FIG. 11f, in the structure shown therein 3005, the photo resist mask is removed by a photo resist etchant and a cleaning process is performed afterwards.

Referring to FIG. 11g, in the structure 3006 shown therein, wet etch is applied using the stripe-shaped oxide pattern as a etch mask. Then, the substrate is etched anisotropically by forming V-shaped trenches. In one instance, the surfaces of the V-shaped trenches are aligned parallel to the (111) crystalline axis of the Silicon. As a silicon etchant, KOH is used. After the etching process is finished, the silicon wafer is cleaned with DI water.

Referring to FIG. 11h, in the structure 3007 shown therein, the oxide mask layer is removed by wet etch using the Hydrofluoric acid (HF) solution.

Referring to FIG. 11i, in the structure 3008 shown therein, an intrinsic amorphous silicon (a-Si) layer is deposited on the surface having alternating concave and convex sections (the surface with the V-shaped trenches). In one instance, not a limitation of these teachings, the intrinsic amorphous silicon layer is deposited by the ALD method. In another instance, not a limitation of these teachings, the intrinsic amorphous silicon layer is deposited by the PEVCD method.

Referring to FIG. 11j, in the structure 3009 shown therein, photo resist is placed on the top of the wafer using the spin coating. Then, conventional lithography is applied to form a photo resist pattern such that alternate ones (for example, odd numbered) of the V-shaped stripe trenches are exposed.

Referring to FIG. 11k, in the structure 3010 shown therein, p-doped a-Si is deposited anisotropically on the photo resist pattern and the exposed V-shaped stripe trenches. In one instance, these teachings not being limited only to that instance, the p-doped a-Si is deposited utilizing sputtering or CVD processes.

Referring to FIG. 11l, in the structure 3011 shown therein, a metal is deposited anisotropically to cover the exposed area as well as the top of the photo resist. Typical metal, these teachings not being limited to only those typical or exemplary metals, for this electrode formation is aluminum (AL). Other exemplary metals such as Au, Ag, Cr, Cu, Ni, Ti, a combination of thereof can also be used.

Referring to FIG. 11m, in the structure 3012 shown therein, Lift-off etch is employed for removing the photo resist and the unwanted a-Si and metal on the photo resist.

Referring to FIG. 11n, in the structure 3013 shown therein, photo resist is deposited and patterned so that other alternate ones (such as, for example, even numbered) of the V-shaped stripe trenches are exposed for next deposition steps.

Referring to FIG. 11o, in the structure 3014 shown therein, n-doped a-Si is deposited anisotropically on the photo resist pattern and the exposed V-shaped stripe trenches. In one instance, these teachings not being limited only to that instance, the p-doped a-Si is deposited utilizing sputtering or CVD processes.

Referring to FIG. 11p, in the structure 3015 shown therein, The same metal used as in the structure 3011 in FIG. 11l is deposited anisotropically to cover the exposed area as well as the top of the photo resist. Referring to FIG. 11q, in the structure 3016 shown therein, Lift-off etch is employed for removing the photo resist and the unwanted a-Si and metal on the photo resist. The deposited metal constitutes the electrode/reflector components 30.

Referring to FIG. 11r, in the structure 3017 shown therein, the a-Si layer between the electrode/reflector components is removed. In one instance, the a-Si layer between the electrode/reflector components is removed dry etching. In this structure, the electrode metal layer functions as the etch mask.

Referring to FIG. 11s, in the structure 3018 shown therein, an oxide is deposited isotropically on the electrode/reflector components and plateau area. In one instance, these teachings not being limited to only that instance, the oxide is SiO₂ or HfO₂. In one instance, these teachings not being limited to only that instance, the oxide is deposited utilizing ALD, CVD or sputtering processes.

Referring to FIG. 11t, in the structure 3019 shown therein, a substantially transparent substrate 320, such as, but not limited to, a glass plate, is bonded, using glue, to the surface on which the oxide was deposited on in FIG. 11s. In one embodiment, a glue allowing removal by UV exposure is utilized; in that embodiment, the glass substrate 320 can be removed later.

Referring to FIG. 11u, in the structure 3020 shown therein, wax is deposited on the substrate and sidewall of the wafer to block the wet etch in the next step.

Referring to FIG. 11v, in the structure 3021 shown therein, the wafer is thinned. A wet etch process is employed to thin the wafer. In one instance, not a limitation of these teachings, KOH is used as an etchant. For a SOI wafer, the etch process removes the handling silicon layer and stops at the SiO₂ interface.

Referring to FIG. 11w, in the structure 3022 shown therein, the SiO₂ is removed. In one instance, another wet etch process is employed to remove the SiO₂. In one instance diluted HF is used as an etchant.

Referring to FIG. 11x, in the structure 3023 shown therein, the wax deposited on the substrate and sidewall of the wafer is removed.

Referring to FIG. 11y, in the structure 3024 shown therein, a thin p-type dopant layer (also referred to as the p doped, delta doped layer) is formed by deposition. In one instance, the p doped, delta doped layer is formed by either by ALD, or CVD. An ALD (atomic layer deposition) technique is typically employed because it deposits without using any plasma energy which tends to damage the silicon surface. The dopant layer can comprise any suitable material, such as, but not limited to, trimethylboron, triisopropylborane ((C₃H₇)₃B), triethoxyborane ((C₂H₅O)₃B, and/or triisopropoxyborane ((C₃H₇O)₃B.

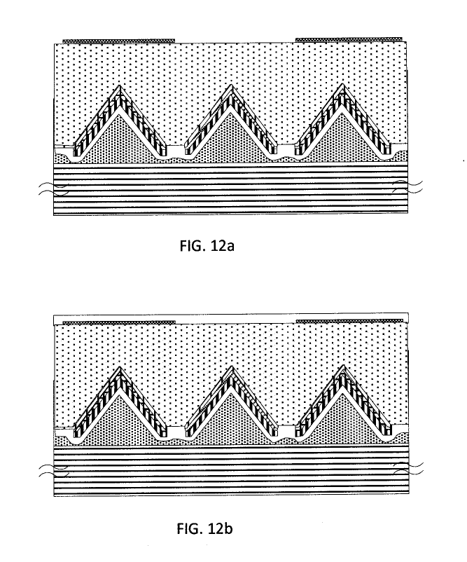

Alternatively, p-type dopant can be implanted by using a conventional ion implantation technique. In this case, the steps producing the structures 1020 and 1023 can be operated. The p-dopant layer, in one instance, can be formed only above substantially the n junction, as shown in FIGS. 12a, 12b (structures 3022B and 3023B). The conventional ion implantation forms a modulated delta doping layer. In the instance that the delta doping layer is a p-type, it is beneficial for electron collection. Unlike photo detectors which collect only a single type of carrier, a photovoltaic device can collect holes and electrons. Having a p doped, delta doping layer over the entire group of p-i-n junctions may not be beneficial for collecting other type of carrier. A modulated p doped, delta doping layer disposed only above substantially the n junctions can enhance the collection of electrons.

Referring to FIG. 11z, in the structure 3025 shown therein, a thin oxide (in one instance, SiO₂) 310 is deposited so that the dopant layer (the delta doped layer) is sandwiched between the silicon and the oxide layer. In one instance, the scene oxide is deposited by ALD.

Referring to FIG. 11aa, in the structure 3026 shown therein, the substantially transparent substrate 320 is detached from the wafer. In one instance, the detachment of the substantially transparent substrate 320 is a result of UV exposure.

Referring to FIG. 11bb, in the structure 3027 shown therein, the detached wafer is cleaned in order to remove substantially any remaining glue.

Referring to FIG. 11zcc, in the structure 3028 shown therein, the dopant is diffused into silicon for forming a shallow, thin p+ doped layer, so called, ‘delta doped layer’ which will result in the surface pinning. In one instance, rapid thermal annealing is employed to implement the diffusion. In one exemplary embodiment, not a limitation of these teachings, the thermal annealing is performed at about 850° C. for about 10 to about 30 minutes under a suitable atmosphere (for example, but not limited to, argon).

Referring to FIG. 11dd, in the structure 3029 shown therein, another substrate 330 is attached for providing a mechanical support as well as for heat spreading. In one instance, a heat conductive glue is deposited on the surface having the grooved electrodes. Then, the substrate 370 is attached. In one typical embodiment, not a limitation of these teachings, a ceramic plate can be used. Other materials such as AL, Cu, Stainless still, carbon fiber reinforced polymer (CFRP), with combination of thereof can be utilized for the substrate 330. It should be noted that these teachings are not limited to only those materials.

Referring to FIG. 11ee, in the structure 3030 shown therein, the thin oxide layer at the surface of the wafer is removed by wet etch using buffered HF. The wafer surface is cleaned afterwards.

Referring to FIG. 11ff, in the structure 3031 shown therein, a thin passivation layer 340 is supposed. In one instance, a Thin HfO₂ layer is deposited as the passivation layer. Other materials such as SiO₂, Al₂O₃, can be used as a passivation layer.

Referring to FIG. 11gg, in the structure 3032 shown therein, an ITO (Indium Tin oxide) layer is deposited by using sputtering or CVD processes. In one instance, the thickness of the deposited ITO is about 1.7 micron. Other materials such as ZnO, ZIO, ZTO, TiO2, and nitride can be used. For embodiments having a planar antireflection layer, as in the structure 3032B shown in FIG. 13, the thickness of the ITO is determined by the desired antireflection property. In one instance, these teachings not being limited to only that instance, for embodiments having a planar antireflection layer, the thickness of the ITO can be about a quarter wavelength of green light, which is the middle of the visible spectrum. For embodiments having a planar reflection layer, the steps necessary to obtain the structures 3033-3039 in FIGS. 11hh through 11nn can be omitted.

Referring to FIG. 11hh, in the structure 3033 shown therein, photo resist is deposited on the ITO. In one instance, the photo resist is deposited by means of a spin coating method. Referring to FIG. 11ii, in the structure 3034 shown therein, the photo resist is patterned. In one instance, the photo resist is patterned by means of e-beam lithography. In one embodiment, not a limitation of these teachings, the shape of the pattern is typically an array of circular holes with about 100 nm diameter and about 800 nm pitch.

Referring to FIG. 11jj, in the structure 3035 shown therein, Aluminum is deposited on the patterned photo resist and the exposed ITO. In one instance, the Aluminum is deposited by using evaporation or sputtering processes.

Referring to FIG. 11kk, in the structure 3036 shown therein, photo resist is removed as well as the Al on the photo resist mask by lift-off process.

Referring to FIG. 11ll, in the structure 3037 shown therein, an ITO pillar array is constructed. In one instance, a dry etch process is employed to make the ITO pillar array. In one exemplary embodiment, not a limitation of these teachings, the ITO pillar array has a height about a 1.5 micron, about a diameter of about 100 nm, and a pitch of about 800 nm.

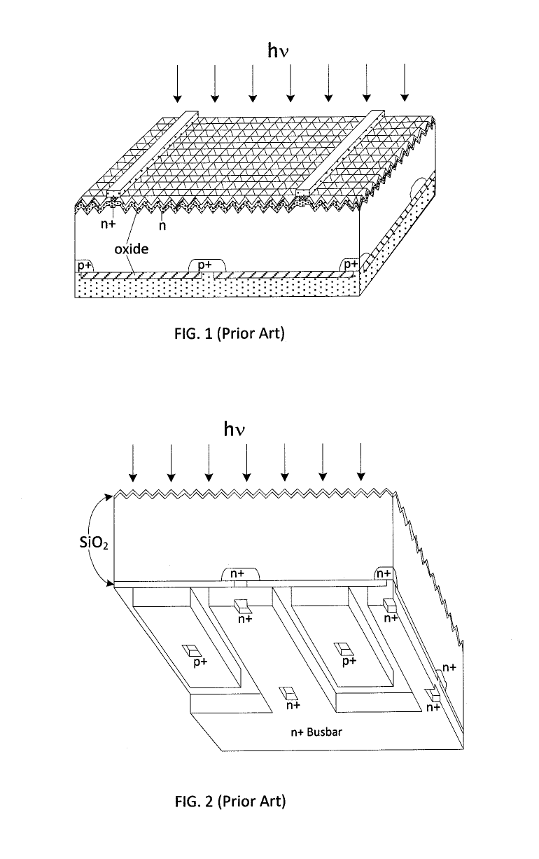

Referring to FIG. 11mm, in the structure 3038 shown therein, Al is removed from the ITO pillars. In one instance, the Al is removed by means of wet etching. Referring to FIG. 1 inn, in the structure 3039 shown therein, ITO is deposited conformally so that end result may form an array of the inverted parabolic cones. In one instance, the ITO is deposited by a combination of ALD and CVD.

Referring to FIG. 11oo, in the structure 3040 shown therein, the edge of the substrate 330 is removed and electrical contacts are formed to connect the V-groove shaped electrodes.

For the purposes of describing and defining the present invention it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Although the invention has been described with respect to various embodiments, it should be realized these teachings are also capable of a wide variety of further and other embodiments within the spirit and scope of the appended claims.

What is claimed is:

1. A device structure comprising:
a substrate on which a surface having alternating concave and convex sections is formed; said surface having alternating concave and convex sections having a plurality of peaks and valleys;
a plurality of electrode/reflector components; each one of said plurality of electrode/reflector components being conformal to at least a portion of a section of the surface having alternating concave and convex sections from one valley to another valley; each electrode/reflector component being electrically isolated from another electrode/reflector component a plurality of p-doped layers, each one p-doped layer disposed over at least a portion of an alternate one of said plurality of electrode/reflector components;
a plurality of n-doped layer, each one n-doped layer disposed over at least a portion of one of other alternate ones of said plurality of electrode/reflector components; one electrode/reflector component having the p-doped layer disposed over said one electrode/reflector component being adjacent to one of said other electrode/reflector components having the n-doped layer disposed over; and
intrinsic silicon material disposed between each of said n-doped layers and each of said p-doped layers.

2. The device structure of claim 1 further comprising a p-doped, delta doped layer located on the surface of the substrate opposite said surface having alternating concave and convex sections.

3. The device structure of claim 1 further comprising at least one anti-reflection layer disposed on the surface of the substrate opposite said surface having alternating concave and convex sections.

4. The device structure of claim 1 wherein the substrate comprises intrinsic silicon.

5. The device structure of claim 4 wherein said each p doped silicon layer is a p doped layer of the substrate; and wherein said each n doped silicon layer is an n doped layer of the substrate.

6. The device structure of claim 5 further comprising a p-doped, delta doped layer located on the surface of the substrate opposite said surface having alternating concave and convex sections; and
at least one anti-reflection layer disposed on the over said p-doped, delta doped layer and opposite said surface having alternating concave and convex sections.

7. The device structure of claim 3 wherein said at least one anti-reflection layer comprises a plurality of cone shaped structures.

8. The device structure of claim 1 wherein the substrate comprises lightly n doped silicon; wherein said p doped silicon layer is a p doped amorphous silicon layer; and wherein said n doped silicon layer is an n doped amorphous silicon layer.

9. The device structure of claim 8 further comprising intrinsic amorphous silicon layers disposed over said p doped silicon layer and over said n doped silicon layer and over the gap between the n doped layer and p doped layer.

10. The device structure of claim 5 further comprising a p-doped, delta doped layer located on the surface of the substrate opposite said surface having alternating concave and convex sections; and at least one anti-reflection layer disposed over said p-doped, delta doped layer and opposite said surface having alternating concave and convex sections.

11. The device structure of claim 10 wherein said at least one anti-reflection layer comprises a plurality of cone shaped structures.

12. The device structure of claim 1 wherein the substrate comprises substantially single crystal silicon.

13. The device structure of claim 1 further comprising:
a first plurality of electrical contacts; each electrical contact from said first plurality being operatively connected to one electrode/reflector component from said alternate ones; and
a second plurality of electrical contacts; each electrical contact from said second plurality being operatively connected to one electrode/reflector component from said other alternate ones.

14. The device structure of claim 13 wherein each electrical contact from said first plurality of electrical contacts is connected in parallel to other electrical contacts from said first plurality of electrical contacts; and wherein each electrical contact from said second plurality of electrical contacts is connected in parallel to other electrical contact from said second plurality of electrical contacts.

15. The device structure of claim 2 wherein said p-doped, delta doped layer comprises a plurality of segments, each segment from said plurality of segments being disposed over alternate sections of the surface having alternating concave and convex sections, said alternate sections extending from one valley to another valley and including one plateau peak; each alternate sections comprising one of said other alternate ones of said plurality of electrode/reflector components.

16. A method for fabricating a device, the method comprising the steps of
Forming, on an intrinsic type substrate, a surface having alternating concave and convex sections;
forming p doped layers over at least a portion of alternate sections of the surface having alternating concave and convex sections; each p doped layer being formed over at least a portion of one alternate section; the alternate sections extending from one valley to another valley and including one plateau;
forming n doped layers over at least a portion of other alternate sections of the surface having alternating concave and convex sections; each n doped layers being formed over at least a portion of one of the other alternate section; the other alternate sections extending from one valley to another valley and including one plateau; and
placing one electrode/reflector component in each section of the surface having alternating concave and convex sections; each section extending from one valley to another valley and including one plateau; each electrode/reflector component being conformal to at least a portion of the section of the surface having alternating concave and convex sections; each electrode/reflector component being electrically isolated from another electrode/reflector component over the plateau area.

17. The method of claim 16 wherein the substrate is a substantially single crystal substrate; and wherein the forming the surface having alternating concave and convex sections comprises forming the surface having alternating concave and convex sections by wet etching along a predetermined crystal orientation surface.

18. The method of claim 17 wherein the substrate is a silicon on insulator (SOI) wafer.

19. The method of claim 16 further comprising forming a p-doped, delta doped layer located on the substrate and above the plateaus.

20. The method of claim 19 wherein the forming of the p-doped, delta doped layer comprises deposition by atomic layer deposition (ALD).

21. The method of claim 19 wherein the forming of the p-doped, delta doped layer comprises deposition by chemical vapor deposition (CVD).

22. The method of claim 19 wherein the forming of the p-doped, delta doped layer comprises forming a plurality of segments of the p-doped, delta doped layer, each segment from said plurality of segments being disposed on an opposing side of the n-doped layers.

23. The method of claim 16 further comprising forming electrical contacts on the p doped layers and the n doped layers.

24. The method of claim 16 further comprising placing at least one anti-reflection layer on the substrate and above the peaks.

25. The method of claim 24 further comprising depositing a passivation layer on substrate before placing the at least one anti-reflection layer; the at least one anti-reflection layer being placed on the passivation layer.

26. The method of claim 25 wherein depositing the passivation layer comprises depositing the passivation layer by ALD.

27. The method of claim 24 wherein the placing of the at least one anti-reflection layer comprises forming at least one anti-reflection layer comprising a plurality of cone shaped structures.

28. A method for fabricating a device, the method comprising the steps of:
forming a surface having alternating concave and convex sections on a lightly doped n type substrate;
depositing an intrinsic amorphous silicon layer over the surface having alternating concave and convex sections;
forming p doped amorphous silicon layers over the intrinsic amorphous silicon layer covering at least a portion of alternate sections of the surface having alternating concave and convex sections; each p doped amorphous silicon layer being formed over at least a portion of one alternate section; the alternate sections extending from one valley to another valley and including one plateau;
forming n doped amorphous silicon layers over the intrinsic amorphous silicon layer covering at least a portion of other alternate sections of the surface having alternating concave and convex sections; each n doped amorphous silicon layers being formed over at least a portion of one of the other alternate section; the other alternate sections extending from one valley to another valley and including one plateau; and
placing one electrode/reflector component in each section of the surface having alternating concave and convex sections; each section extending from one valley to another valley and including one plateau; each electrode/reflector component being conformal to at least a portion of the section of the surface having alternating concave and convex sections; each electrode/reflector component being electrically isolated from another electrode/reflector component over the plateau between two neighboring valleys.

29. The method of claim 28 wherein the substrate is a substantially single crystal substrate; and wherein the forming the surface having alternating concave and convex sections comprises forming the surface having alternating concave and convex sections by wet etching along a predetermined crystal orientation surface.

30. The method of claim 29 wherein the substrate is a silicon on insulator (SOI) wafer.

31. The method of claim 28 further comprising forming a p-doped, delta doped layer located on surface of the substrate and opposite said surface having alternating concave and convex sections.

32. The method of claim 31 wherein the forming of the p-doped, delta doped layer comprises deposition by atomic layer deposition (ALD).

33. The method of claim 31 wherein the forming of the p-doped, delta doped layer comprises deposition by chemical vapor deposition (CVD).

34. The method of claim 31 wherein the forming of the p-doped, delta doped layer comprises forming a plurality of segments of the p-doped, delta doped layer, each segment from said plurality of segments being disposed above the n-doped layers.

35. The method of claim 28 further comprising forming electrical contacts on the p doped amorphous silicon layers and the n doped amorphous silicon layers.

36. The method of claim 28 further comprising placing at least one anti-reflection layer on surface of the substrate opposite said surface having alternating concave and convex sections.

37. The method of claim 36 further comprising depositing a passivation layer on substrate before placing the at least one anti-reflection layer; the at least one anti-reflection layer being placed on the passivation layer.

38. The method of claim 37 wherein depositing the passivation layer comprises depositing the passivation layer by ALD.

39. The method of claim 36 wherein the placing of the at least one anti-reflection layer comprises forming at least one anti-reflection layer comprising a plurality of cone shaped structures.

40. The method of claim 28 wherein the intrinsic amorphous silicon layer is deposited using ALD.

41. The method of claim 28 wherein the intrinsic amorphous silicon layer is deposited using plasma enhanced chemical vapor deposition (PE CVD).
